(19) United States
(12) Patent Application Publication
(10) Pub. No.: US 2024/0372528 A1
(43) Pub. Date: Nov. 7, 2024

(54) ACOUSTIC RESONATOR AND METHOD FOR MANUFACTURING ACOUSTIC RESONATOR

(71) Applicant: AAC Technologies Pte. Ltd., Singapore (SG)

(72) Inventors: DongLiang Pang, Singapore (SG); LiEng Loo, Singapore (SG); Kahkeen Lai, Singapore (SG); Ke Wu, Shenzhen (CN); ShirNee Yap, Singapore (SG)

(21) Appl. No.: 18/313,351

(22) Filed: May 7, 2023

(51) Int. Cl. H03H 9/17; H03H 3/02; H03H 9/02

(52) U.S. Cl. CPC H03H 9/173; H03H 3/02; H03H 9/02047; H03H 2003/021

(57) ABSTRACT

An acoustic resonator and a manufacture method thereof. The acoustic resonator includes: a substrate having cavities; piezoelectric units one by one corresponding to the cavities, the piezoelectric units cover the cavities, and each piezoelectric unit includes a first electrode layer, a piezoelectric layer and a second electrode layer sequentially stacked from bottom to top; a protective layer stacked on the piezoelectric unit; a series unit having one end electrically connected to the first electrode layer of one of the piezoelectric units, and the other end electrically connected to the second electrode layer of another one of the piezoelectric units, so as to connect the two piezoelectric units in series. Compared with the 10 related art, the piezoelectric unit is protected from further risk of damages in subsequent manufacturing processes by providing a protective layer on the piezoelectric unit, so that the acoustic resonator has better Q value and coupling coefficient.

### TECHNICAL FIELD

The present invention relates to the technical field of semiconductors and, in particular, to an acoustic resonator and a method for manufacturing an acoustic resonator.

### BACKGROUND

Film acoustic resonators (FBAR) are devices with piezoelectric materials and structures that can form (inverse) piezoelectric effect, and have the characteristics of high sensitivity, high operation frequency and low power consumption. The core component of FBAR is a piezoelectric unit composed of a first electrode layer, a piezoelectric layer, and a second electrode layer. By applying a voltage on the first electrode layer and the second electrode layer, the piezoelectric layer deforms. When an alternating voltage is applied, the piezoelectric element will generate piezoelectric effect and inverse piezoelectric effect, so that the signal is transmitted. FBAR devices can be used to form bandpass filters, which allow the radio frequency range to pass through while rejecting frequencies out of the radio frequency range, and which are connected in series and parallel to achieve this filtering of frequency.

In the related art, current manufacturing methods post piezoelectric layer deposition will cause damage to the surface of piezoelectric layer thus having a negative impact on the Q factor, coupling coefficient of the resonator and other parameters.

### SUMMARY

The object of the present invention is to provide an acoustic resonator and a method for manufacturing the acoustic resonator, which solve the technical problems of the related art in order to protect the piezoelectric unit from further risk of damages in subsequent manufacturing processes.

In a first aspect, the present invention provides an acoustic resonator, including: a substrate having a plurality of cavities; a plurality of piezoelectric units one by one corresponding to the plurality of cavities, the piezoelectric units cover the cavities, and each of the piezoelectric units comprises a first electrode layer, a piezoelectric layer and a second electrode layer sequentially stacked from bottom to top; a protective layer stacked on the piezoelectric unit; a series unit having one end electrically connected to the first electrode layer of one of the piezoelectric units, and the other end electrically connected to the second electrode layer of another one of the piezoelectric units, so as to connect the two piezoelectric units in series.

As an improvement, an intermediate metal layer and at least one shunt metal layer are sequentially stacked between the piezoelectric layer and the second electrode layer from top to bottom.

As an improvement, the series unit includes a bridge metal layer and an electrode lead structure, one end of the electrode lead structure is electrically connected to the first electrode of one of the piezoelectric units, the other end of the electrode lead structure is electrically connected to the bridge metal layer of another one of the piezoelectric units, and the bridge metal layer on the another piezoelectric unit is electrically connected to the second electrode layer of the corresponding piezoelectric unit.

As an improvement, the bridge metal layer is covered with a passivation layer.

In a second aspect, the present invention also provides a method for manufacturing an acoustic resonator, including: providing a substrate; forming at least one cavity on the substrate by etching; depositing a sacrificial layer in each of the at least one cavity; depositing piezoelectric units corresponding to the at least one cavity one by one, the piezoelectric units cover the at least one cavity, and each of the piezoelectric units comprises a first electrode layer, a piezoelectric layer, an intermediate metal layer, a shunt metal layer and a second electrode layer sequentially stacked from bottom to top; depositing a protective layer and an oxide layer on the piezoelectric unit; depositing a series unit to connect the piezoelectric units in series; depositing a passivation layer on the series unit; and removing the sacrificial layer and the oxide layer.

As an improvement, the series unit comprising a bridge metal layer and an electrode lead structure, wherein the bridge metal layer is electrically connected to the second electrode layer of one of the piezoelectric units, one end of the electrode lead structure is electrically connected to the first electrode layer of one of the piezoelectric units, the other end of the electrode lead structure is electrically connected to the bridge metal layer of another one of the piezoelectric units, and the bridge metal layer of the another piezoelectric unit is electrically connected to the second electrode layer of the corresponding piezoelectric unit; the passivation layer is deposited on the electrode lead structure.

As an improvement, the protective layer is made of aluminum nitride.

As an improvement, the first electrode layer, the second electrode layer, the intermediate metal layer and the shunt metal layer are all made of same material.

As an improvement, the sacrificial layer is made of phospho-silicate glass.

As an improvement, the piezoelectric layer is made of lead zirconium titanate, aluminum nitride, zinc oxide or barium titanate.

As an improvement, the passivation layer is made of aluminum nitride.

Compared with the related art, the present invention protects the piezoelectric unit from further risk of damages in subsequent manufacturing processes by providing a protective layer on the piezoelectric unit, so that the acoustic resonator has better Q value and coupling coefficient.

### BRIEF DESCRIPTION OF DRAWINGS

FIG. 1 is a schematic cross-sectional view of an acoustic resonator according to an embodiment of the present invention; and

FIGS. 2A-2N are flow diagrams of the manufacture of an acoustic resonator according to embodiments of the present invention.

### REFERENCE SIGNS

1—substrate, 2—cavity, 3—sacrificial layer, 4—first electrode layer, 5—piezoelectric layer, 6—intermediate metal layer, 7—shunt metal layer, 8—second electrode layer, 9—protective layer, 10—oxide layer, 11—bridge metal layer, 12—electrode lead structure, 13—passivation layer, 14—first opening, 15—second opening, 16—third opening.

### DESCRIPTION OF EMBODIMENTS

Embodiments described below with reference to the drawings are exemplary only for explaining the present invention and should not be construed as limiting the present invention.

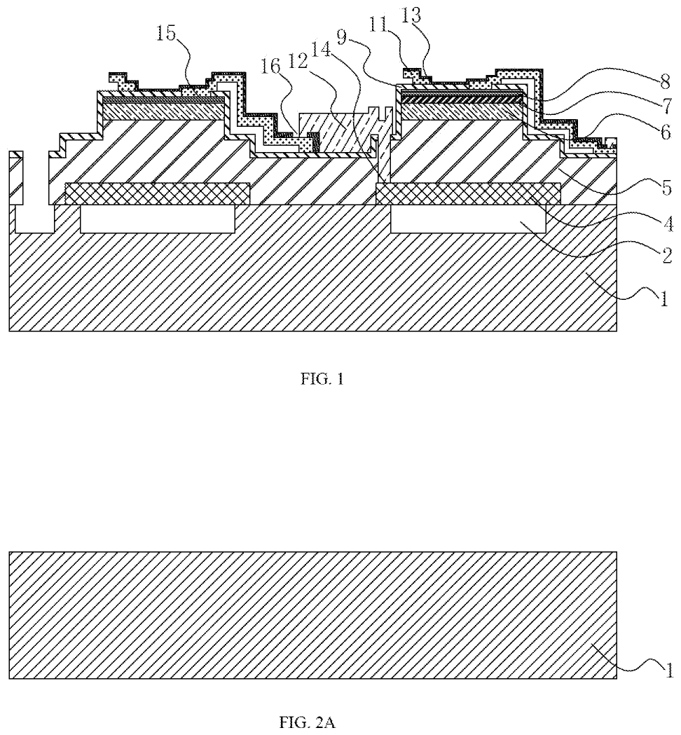

As shown in FIG. 1, FIG. 1 is a schematic cross-sectional view of an acoustic resonator according to an embodiment of the present invention. An embodiment of the present invention provides an acoustic resonator, including a substrate 1, a piezoelectric unit, a protective layer 9 and a series unit arranged on the substrate 1 from top to bottom.

The substrate 1 has a plurality of cavities 2 for forming bulk acoustic wave reflecting interfaces. A plurality of piezoelectric units correspond to cavities 2 one by one. The piezoelectric units cover the cavities 2. The piezoelectric unit includes a first electrode layer 4, a piezoelectric layer 5 and a second electrode layer 8 stacked sequentially from bottom to top.

The first electrode layer 4 is formed on the substrate 1 by electron beam lift-off or magnetron sputtering, and is patterned using a photolithography process. The material of the first electrode layer 4 may be one or more of Al, Mo, W, Pt, Cu, Ag, Au, ZrN, and may also be other materials having good electrical conductivity. For example, the first electrode layer 4 is made of molybdenum (Mo).

The piezoelectric layer 5 is deposited on the first electrode layer 4. The piezoelectric layer 5 has the characteristics of generating mechanical vibration in the presence of an electric field and the characteristics of generating an electric field when the mechanical vibration occurs. The piezoelectric layer 5 can be made of zirconium lead titanate, aluminum nitride, zinc oxide or barium titanate or any other piezoelectric material. For example, the piezoelectric layer 5 is made of aluminum nitride.

The second electrode layer 8 is formed on the piezoelectric layer 5 by electron beam lift-off or magnetron sputtering, and is patterned using a photolithography process. The material of the second electrode layer 8 may be one or more of Al, Mo, W, Pt, Cu, Ag, Au, ZrN, and may be other materials having good electrical conductivity. For example, the second electrode layer 8 is made of molybdenum (Mo).

In an embodiment of the present invention, the first electrode layer 4 and the second electrode layer 8 are located on opposite sides of the piezoelectric layer 5. The direction of the electric field is the thickness direction of the piezoelectric layer 5, and an axial orientation of the piezoelectric layer 5 is inclined in relative to the direction of the electric field. As a result, the generated bulk acoustic wave is well reflected at the interface between the electrode and the air, so that the bulk acoustic wave is confined in the piezoelectric layer 5 and thus the energy loss is small.

As shown in FIG. 1, there is a gap between the first electrode layers 4 of adjacent piezoelectric units, the piezoelectric layer 5 fills the gap, and an orthographic projection of the second electrode layer 8 in the thickness direction of the substrate 1 falls in the cavity 2. The region on the piezoelectric layer 5 not covered by the second electrode layer 8 forms a stepped interface.

The protective layer 9 is formed on the piezoelectric unit by electron beam stripping or magnetron sputtering. In an embodiment, the protective layer 9 and the piezoelectric layer 5 are made of the same material, which may be aluminum nitride. This protects the piezoelectric unit from further risk of damages during subsequent manufacturing processes, thereby bringing better Q value and coupling coefficient of the acoustic resonator.

One end of the series unit is electrically connected to the first electrode layer 4 of one piezoelectric unit, and the other end of the series unit is electrically connected to the second electrode layer 8 of another piezoelectric unit, to connect the two piezoelectric units in series to create a bandpass filter. The radio frequency range is allowed to pass while frequencies outside the frequency range are rejected.

Further, as shown in FIG. 1, between the piezoelectric layer 5 and the second electrode layer 8, an intermediate metal layer 6 and at least one shunt metal layer 7 are stacked sequentially from top to bottom, which has greater flexibility in frequency tuning, and can meet more bandwidths. In an embodiment, the shunt metal layer 7 can be one layer or multiple layers, and the intermediate metal layer 6 is located on the piezoelectric layer 5 of each piezoelectric unit. The shunt metal layer 7 is located on the piezoelectric layer 5 of one or more piezoelectric units, which is not limited herein. In an embodiment, the materials of the middle metal layer 6 and the shunt metal layer 7 are the same as those of the first electrode layer 4 and the second electrode layer 8, which may be molybdenum. Those skilled in the art can understand that Cu, Au, Ag, Pt, Ru and the like can also be used, which can also achieve the technical effect of the present invention.

Further, as shown in FIG. 1, the series unit includes a bridge metal layer 11 and an electrode lead structure 12. A first opening 14 is formed on one of the piezoelectric units, and the first opening 14 is located on the piezoelectric layer 5 of one of the piezoelectric units that is not covered by the second electrode layer 8. The first opening 14 sequentially penetrates through the protective layer 9 and the piezoelectric layer 5, to expose the first electrode layer 4. A second opening 15 is formed on the other piezoelectric unit, and the second opening 15 is located on the protective layer 9 of another piezoelectric unit. The second opening 15 penetrates through the protective layer 9 to expose the second electrode layer 8. One end of the electrode lead structure 12 passes through the first opening 14 and electrically connected to the first electrode layer 4 of one piezoelectric element, the other end of the electrode lead structure 12 is electrically connected to the bridge metal layer 11 of another piezoelectric unit, and the bridge metal layer 11 on the another piezoelectric unit passes through the second opening 15 and is electrically connected to the second electrode layer 8 of the corresponding piezoelectric unit.

The bridge metal layer 11 is covered with a passivation layer 13, and a third opening 16 is formed on the passivation layer 13 to expose the bridge metal layer 11. One end of the electrode lead structure 12 passes through the first opening 14 and is electrically connected to the first electrode layer 4 of one piezoelectric unit, and the other end of the electrode lead structure 12 is electrically connected to the bridge metal layer 11 of another piezoelectric unit through the third opening 16. In an embodiment, the passivation layer 13 is made of aluminum nitride.

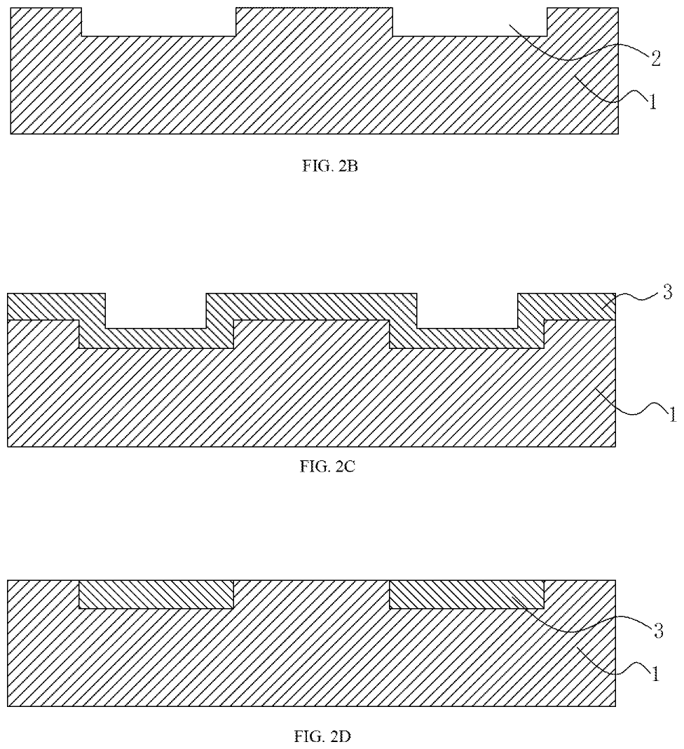

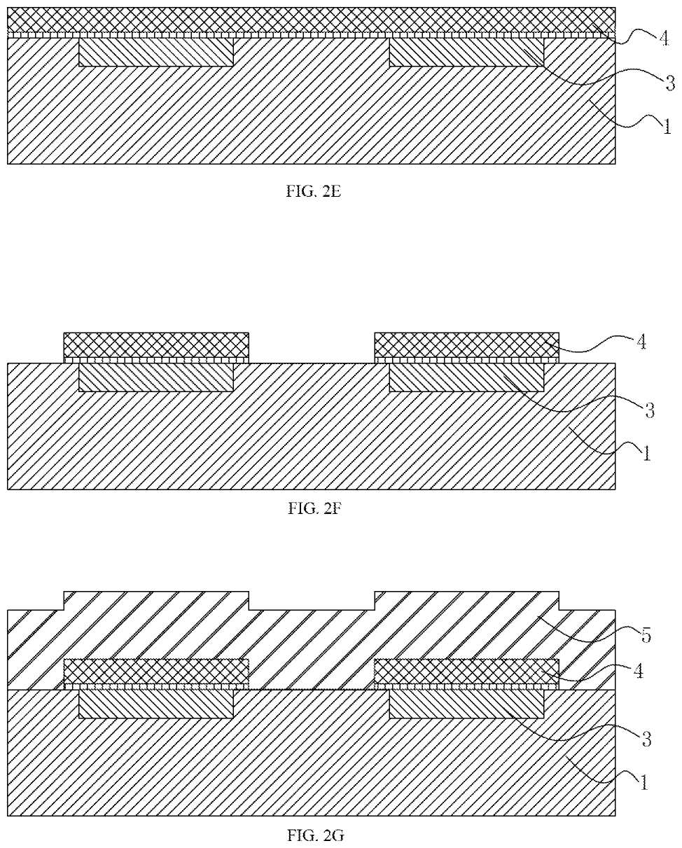

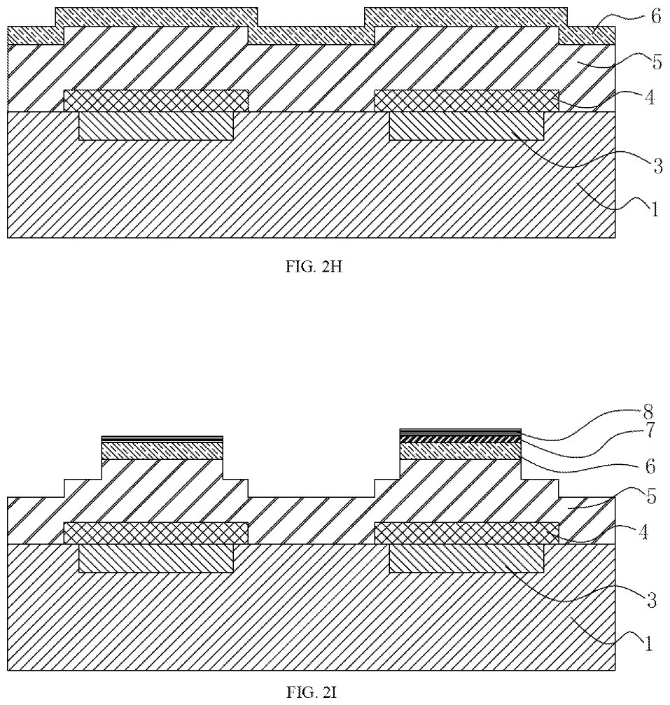

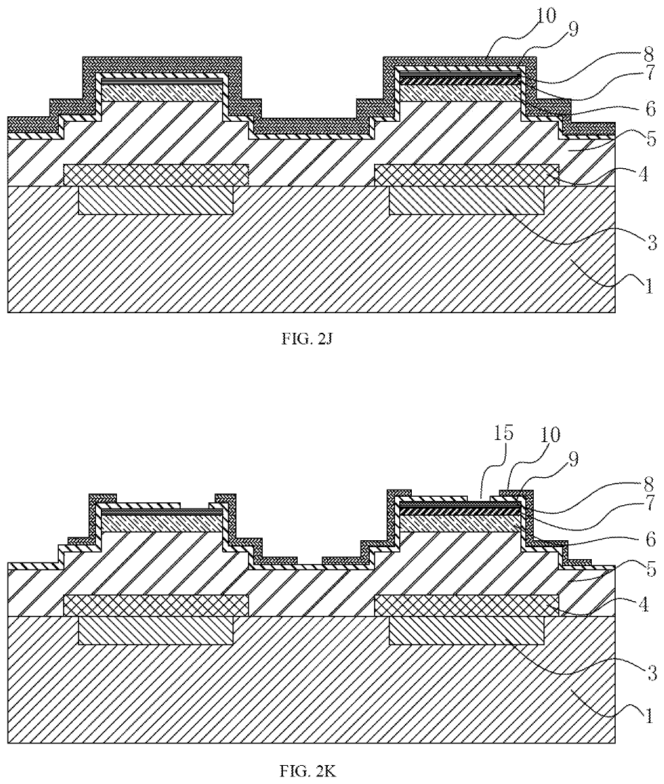

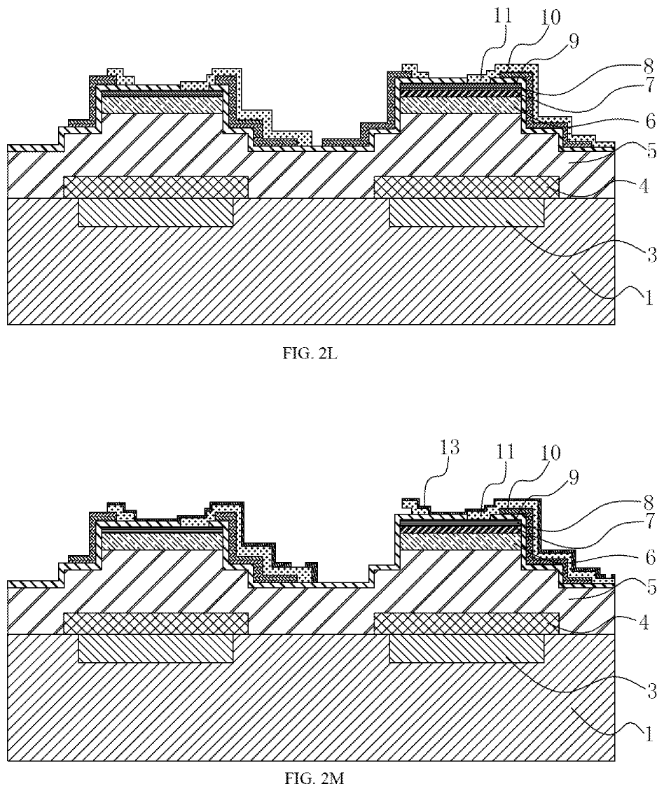

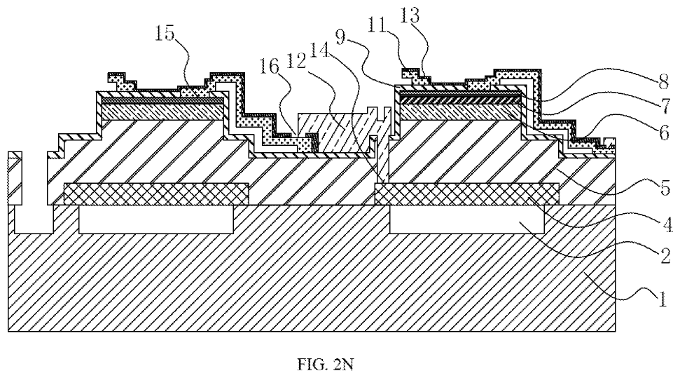

FIGS. 2A-2N are flow diagrams of the manufacture of an acoustic resonator according to embodiments of the present invention. The manufacture method includes the following process:

S101: Referring to FIG. 2A, providing a substrate 1, the material of the substrate 1 can be selected from Si, SiC, sapphire or spinel. Before the manufacture starts, RCA cleaning is performed on the substrate 1 to remove the substrate contamination particles on the substrate 1;

S102: Referring to FIG. 2B, forming a cavity 2 on the substrate 1 by photolithography or etching;

S103: Referring to FIG. 2C, filling the cavity 2 with a sacrificial layer 3, the sacrificial layer 3 may be made of phospho-silicate glass;

S104: Referring to FIG. 2D, removing excess material of the sacrificial layer 3 by chemical mechanical polishing so that the sacrificial layer 3 is completely filled in the cavity 2;

S105: Referring to FIG. 2E, forming a first electrode layer 4 on the substrate 1 by electron beam lift-off or magnetron sputtering, and patterning the first electrode layer 4 using a photolithography process;

S106: Referring to FIG. 2F, the first electrode layer 4 is divided into a plurality of independent first electrode layers 4 by photolithography or etching process, and each cavity 2 corresponds to a first electrode layer 4;

S107: Referring to FIG. 2G, depositing a piezoelectric layer 5 by electron beam lift-off or magnetron sputtering on the first electrode layer 4;

S108: Referring to FIG. 2H, depositing an intermediate metal layer 6 on the piezoelectric layer 5 by electron beam lift-off or magnetron sputtering;

S109: Referring to FIG. 2I, etching the intermediate metal layer 6 and the piezoelectric layer 5 by photolithography or etching process to form a stepped interface, and sequentially depositing a shunt metal layer 7 and a second electrode layer 8 on the intermediate metal layer 6;

S110: Referring to FIG. 2J, sequentially forming a protective layer 9 and an oxide

layer 10 by electron beam lift-off or magnetron sputtering;

S111: Referring to FIG. 2K, forming a second opening 15 is opened on the protective layer 9 by photolithography or etching process, and the second electrode layer 8 is exposed from the second opening 15;

S112: Referring to FIG. 2L, depositing a bridge metal layer 11, and one end of the bridge metal layer 11 is electrically connected to the second electrode layer 8 through the second opening 15;

S113: Referring to FIG. 2M, depositing a passivation layer 13, and forming a third opening 16 on the passivation layer 13, the bridge metal layer 11 is exposed from the third opening 16;

S114: Referring to FIG. 2N, forming a first opening 14 by photolithography or etching process, the first electrode layer 4 is exposed from the first opening 14, and depositing an electrode lead structure 12, one end of the electrode lead structure 12 is electrically connected to the first electrode layer 4 of one piezoelectric unit through the first opening 14, and the other end of the electrode lead structure 12 is electrically connected to the bridge metal layer 11 of another piezoelectric unit through the third opening 16;

S115: removing the sacrificial layer 3 and the oxide layer 10.

The structures, features and effects of the present invention have been described in detail above based on the embodiments shown in the drawings. The above descriptions are only preferred embodiments of the present invention, but the present invention is not limited to the embodiments shown in the drawings. Changes or modifications made based on the concept of the present invention are still within the protection scope of the present invention.

What is claimed is:

1. An acoustic resonator, comprising:
a substrate having a plurality of cavities;
a plurality of piezoelectric units one by one corresponding to the plurality of cavities, wherein the piezoelectric units cover the cavities, and each of the piezoelectric units comprises a first electrode layer, a piezoelectric layer and a second electrode layer sequentially stacked from bottom to top;
a protective layer stacked on the piezoelectric unit; and
a series unit having one end electrically connected to the first electrode layer of one of the piezoelectric units, and the other end electrically connected to the second electrode layer of another one of the piezoelectric units, so as to connect the two piezoelectric units in series.

2. The acoustic resonator according to claim 1, wherein an intermediate metal layer and at least one shunt metal layer are sequentially stacked between the piezoelectric layer and the second electrode layer from bottom to top.

3. The acoustic resonator according to claim 1, wherein the series unit comprises a bridge metal layer and an electrode lead structure, one end of the electrode lead structure is electrically connected to the first electrode of one of the piezoelectric units, the other end of the electrode lead structure is electrically connected to the bridge metal layer of another one of the piezoelectric units, and the bridge metal layer on the another piezoelectric unit is electrically connected to the second electrode layer of the corresponding piezoelectric unit.

4. The acoustic resonator according to claim 3, wherein the bridge metal layer is covered with a passivation layer.

5. A method for manufacturing an acoustic resonator, comprising:
providing a substrate;
forming at least one cavity on the substrate by etching;
depositing a sacrificial layer in each of the at least one cavity;
depositing piezoelectric units corresponding to the at least one cavity one by one, wherein the piezoelectric units cover the at least one cavity, and each of the piezoelectric units comprises a first electrode layer, a piezoelectric layer, an intermediate metal layer, a shunt metal layer and a second electrode layer sequentially stacked from bottom to top;
depositing a protective layer and an oxide layer on the piezoelectric unit;
depositing a series unit to connect the piezoelectric units in series;
depositing a passivation layer on the series unit; and
removing the sacrificial layer and the oxide layer.

6. The method for manufacturing an acoustic resonator according to claim 5, wherein the series unit comprising a bridge metal layer and an electrode lead structure, wherein the bridge metal layer is electrically connected to the second electrode layer of one of the piezoelectric units, one end of the electrode lead structure is electrically connected to the first electrode layer of one of the piezoelectric units, the other end of the electrode lead structure is electrically connected to the bridge metal layer of another one of the piezoelectric units, and the bridge metal layer of the another piezoelectric unit is electrically connected to the second electrode layer of the corresponding piezoelectric unit; wherein the passivation layer is deposited on the electrode lead structure.

7. The method for manufacturing an acoustic resonator according to claim 5, wherein the protective layer is made of aluminum nitride.

8. The method for manufacturing an acoustic resonator according to claim 5, wherein the first electrode layer, the second electrode layer, the intermediate metal layer and the shunt metal layer are all made of same material.

9. The method for manufacturing an acoustic resonator according to claim 5, wherein the sacrificial layer is made of phospho-silicate glass.

10. The method for manufacturing an acoustic resonator according to claim 5, wherein the piezoelectric layer is made of lead zirconium titanate, aluminum nitride, zinc oxide or barium titanate.

11. The method for manufacturing an acoustic resonator according to claim 5, wherein the passivation layer is made of aluminum nitride.
